(19) United States
(12) Patent Application Publication
(10) Pub. No.: US 2022/0090264 A1
(43) Pub. Date: Mar. 24, 2022

(54) SUBSTRATE PROCESSING APPARATUS

(71) Applicant: KOKUSAI ELECTRIC CORPORATION, Tokyo (JP)

(72) Inventors: Takashi YAHATA, Toyama-shi (JP); Naofumi OHASHI, Toyama-shi (JP); Tadashi TAKASAKI, Toyama-shi (JP)

(73) Assignee: KOKUSAI ELECTRIC CORPORATION, Tokyo (JP)

(21) Appl. No.: 17/208,299

(22) Filed: Mar. 22, 2021

(30) Foreign Application Priority Data
Sep. 23, 2020 (JP) 2020-158263

(51) Int. Cl. C23C 16/52; C23C 16/44; C23C 16/458

(52) U.S. Cl. CPC C23C 16/52; C23C 16/4412; H01L 21/67017; C23C 16/4408; C23C 16/4583

(57) ABSTRACT

There is provided a technique that includes: a plurality of process chambers in which substrates are processed; a gas supplier configured to supply a gas to the process chambers; a plurality of process chamber exhaust pipes respectively connected to the plurality of process chambers; a common gas exhaust pipe disposed such that the respective process chamber exhaust pipes join together at downstream sides of the process chamber exhaust pipes; at least one detector configured to detect states of pressures in the process chamber exhaust pipes; and a plurality of inert gas supply pipes respectively connected to the process chamber exhaust pipes and configured to supply an inert gas into the process chamber exhaust pipes.

### CROSS-REFERENCE TO RELATED APPLICATION

This application is based upon and claims the benefit of priority from Japanese Patent Application No. 2020-158263, filed on Sep. 23, 2020, the entire contents of which are incorporated herein by reference.

### TECHNICAL FIELD

The present disclosure relates to a substrate processing apparatus.

### BACKGROUND

In the related art, a substrate processing apparatus used in a process of manufacturing a semiconductor device includes, for example, a plurality of process chambers in which substrates are processed, and an exhaust system shared by the respective process chambers. Specifically, the exhaust system is configured such that exhaust pipes are connected to the plurality of process chambers respectively and the exhaust pipes join together at downstream sides of the exhaust pipes. In the substrate processing apparatus of such a configuration, a productivity may be improved by processing the substrates similarly in the respective process chambers.

In the plurality of process chambers, variations may occur in a processing performance due to a problem such as a processing accuracy, an assembling accuracy, and the like of components used. Since the variations in the processing performance may lead to variations in processing results in the respective process chambers, a yield of processing the substrates may be lowered, thereby hindering productivity improvement.

### SUMMARY

Some embodiments of the present disclosure provide a technique capable of maintaining a high productivity when including a plurality of process chambers.

According to some embodiments of the present disclosure, there is provided a technique that includes: a plurality of process chambers in which substrates are processed; a gas supplier configured to supply a gas to the process chambers; a plurality of process chamber exhaust pipes respectively connected to the plurality of process chambers; a common gas exhaust pipe disposed such that the respective process chamber exhaust pipes join together at downstream sides of the process chamber exhaust pipes; at least one detector configured to detect states of pressures in the process chamber exhaust pipes; and a plurality of inert gas supply pipes respectively connected to the process chamber exhaust pipes and configured to supply an inert gas into the process chamber exhaust pipes.

### BRIEF DESCRIPTION OF DRAWINGS

The accompanying drawings, which are incorporated in and constitute a part of the specification, illustrate some embodiments of the present disclosure.

FIG. 1 is a schematic configuration diagram of a substrate processing apparatus according to some embodiments of the present disclosure.

FIG. 2 is a configuration diagram of a chamber of a substrate processing apparatus according to some embodiments of the present disclosure.

FIG. 3 is a configuration diagram of a controller of a substrate processing apparatus according to some embodiments of the present disclosure.

FIG. 4 is a flowchart of substrate processing according to some embodiments of the present disclosure.

FIG. 5 is a flowchart of an exhaust regulation step according to some embodiments of the present disclosure.

FIG. 6 is a flowchart of a film-processing step according to some embodiments of the present disclosure.

FIG. 7 is a schematic configuration diagram of a substrate processing apparatus according to other embodiments of the present disclosure.

### DETAILED DESCRIPTION

Reference will now be made in detail to various embodiments, examples of which are illustrated in the accompanying drawings. In the following detailed description, numerous specific details are set forth to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of the present disclosure will now be described.

### EMBODIMENTS

First, some embodiments of the present disclosure will be described with reference to the drawings.

### (1) Configuration of the Substrate Processing Apparatus

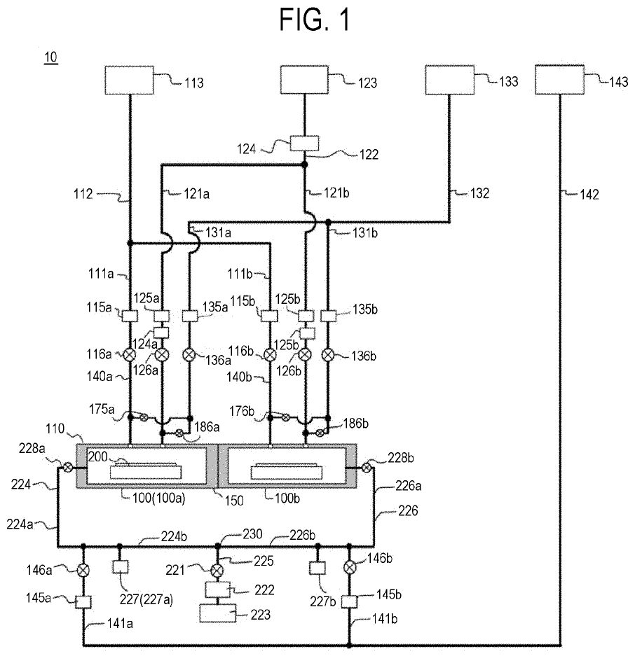

FIG. 1 is a schematic configuration diagram of a substrate processing apparatus according to some embodiments of the present disclosure.

As illustrated in FIG. 1, a substrate processing apparatus 10 largely includes a process module 110, and a gas supplier and a gas exhaust part connected to the process module 110.

### (Process Module)

The process module 110 includes a chamber 100 in which a predetermined processing is performed on a substrate 200. The chamber 100 includes a chamber 100a and a chamber 100b. That is, the process module 110 includes a plurality of chambers 100a and 100b. A partition wall 150 is installed between the chambers 100a and 100b such that internal atmospheres of the respective chambers 100a and 100b are not mixed. A detailed structure of the chamber 100 is described below.

The substrate 200 to be processed may include, for example, a semiconductor wafer substrate (hereinafter, simply referred to as a “wafer”) in which a semiconductor integrated circuit device (semiconductor device) is built. Further, the substrate 200 to be processed is sometimes referred to as a product substrate, which is different from a dummy substrate as described below.

### (Gas Supplier)

A gas supplier configured to supply a processing gas or the like to each of the chambers 100a and 100b is connected to the process module 110. The gas supplier includes a first gas supplier (processing gas supplier), a second gas supplier (reaction gas supplier), and a third gas supplier (first inert gas supplier). In addition to these, a fourth gas supplier (second inert gas supplier) is installed. A composition of each gas supplier is be described below.

### (First Gas Supplier)

First processing gas supply pipes 111a and 111b are connected to the respective chambers 100a and 100b, and a first processing gas common supply pipe 112 is connected to the first processing gas supply pipes 111a and 111b. A first processing gas source 113 is disposed at an upstream side of the first processing gas common supply pipe 112. Mass flow controllers (MFCs) 115a and 115b, and valves 116a and 116b near a process chamber are installed between the first processing gas source 113 and the chambers 100a and 100b sequentially from the corresponding upstream sides, respectively. The first gas supplier (processing gas supplier) includes the first processing gas common supply pipe 112, the MFCs 115a and 115b, the valves 116a and 116b near the process chamber, and first processing gas supply pipes 111a and 111b as a first gas supply pipe. Further, the first processing gas source 113 may be included in the first gas supplier.

A precursor gas as a first processing gas, which is a processing gas, is supplied from the first processing gas source 113. In the present disclosure, the precursor gas contains a first element, and the first element is, for example, silicon (Si). That is, the precursor gas is, for example, a silicon-containing gas. Specifically, a dichlorosilane (SiH₂Cl₂, hereinafter referred to as a “DCS”) gas is used as the silicon-containing gas.

### (Second Gas Supplier)

Second processing gas supply pipes 121a and 121b are connected to the respective chamber 100a and 100b, and a second processing gas common supply pipe 122 is connected to the second processing gas supply pipes 121a and 121b. A second processing gas source 123 is disposed at an upstream side of the second processing gas common supply pipe 122. MFCs 125a and 125b, remote plasma units (RPUs) 124a and 124b as activation parts, and valves 126a and 126b near the process chamber are installed between the second processing gas source 123 and the chambers 100a and 100b sequentially from the corresponding upstream sides, respectively. Instead of the RPUs 124a and 124b, an RPU 124 may be installed on the second processing gas common supply pipe 122. The second gas supplier (reaction gas supplier) includes the RPUs 124, 124a and 124b, the MFCs 125a and 125b, the valves 126a and 126b near the process chamber, the second processing gas common supply pipe 122, and the second processing gas supply pipes 121a and 121b as a second gas supply pipe. Further, the second processing gas source 123 may be included in the second gas supplier.

A reaction gas as a second processing gas, which is a processing gases, is supplied from the second processing gas source 123. The reaction gas is, for example, an oxygen-containing gas. Specifically, for example, an oxygen (02) gas is used as the oxygen-containing gases.

### (Third Gas Supplier)

First inert gas supply pipes 131a and 131b are connected to the first processing gas supply pipes 111a and 111b and the second processing gas supply pipes 121a and 121b. Further, a first inert gas common supply pipe 132 is connected to the first inert gas supply pipes 131a and 131b. A first inert gas (purge gas) source 133 is disposed at an upstream side of the first inert gas common supply pipe 132. MFCs 135a and 135b, valves 136a and 136b near the process chamber, and valves 176a, 176b, 186a, and 186b are installed between the first inert gas source 133 and the chambers 100a and 100b sequentially from the corresponding upstream sides, respectively. The third gas supplier (first inert gas supplier) includes the MFCs 135a and 135b, the valves 136a and 136b near the process chamber, the valves 176a, 176b, 186a and 186b, the first inert gas common supply pipe 132, and the first inert gas supply pipes 131a and 131b. Further, the first inert gas source 133 may be included in the third gas supplier. Further, similar components may be increased or decreased according to the number of process modules installed at the substrate processing apparatus 10.

An inert gas (purge gas) is supplied from the first inert gas source 133. For example, a nitrogen (N₂) gas is used as the inert gas.

### (Fourth Gas Supplier)

Second inert gas supply pipes 141a and 141b are connected to exhaust pipes 224 and 226 of the gas exhaust part to be described below, and a second inert gas common supply pipe 142 is connected to the second inert gas supply pipes 141a and 141b. A second inert gas source 143 is disposed at an upstream side of the second inert gas common supply pipe 142. MFCs 145a and 145b and valves 146a and 146b are installed between the second inert gas source 143 and the exhaust pipes 224 and 226 sequentially from the corresponding upstream sides, respectively. The fourth gas supplier (second inert gas supplier) includes the MFCs 145a and 145b, the valves 146a and 146b, the second inert gas common supply pipe 142, and the second inert gas supply pipes 141a and 141b. Further, the second inert gas source 143 may be included in the fourth gas supplier.

An inert gas is supplied from the second inert gas source 143. For example, a nitrogen (N₂) gas is used as the inert gas. Further, the gas sources of the third gas supplier and the fourth gas supplier are separately configured herein, but may be integrated to be one gas source.

### (Gas Exhaust Part)

The gas exhaust part configured to exhaust an internal atmosphere of the chamber 100a and an internal atmosphere of the chamber 100b is connected to the process module 110. Specifically, a process chamber exhaust pipe 224 is connected to the chamber 100a, and a process chamber exhaust pipe 226 is connected to the chamber 100b. That is, a plurality of process chamber exhaust pipes 224 and 226 are respectively connected to the plurality of chambers 100a. Further, a common gas exhaust pipe 225 is connected to the process chamber exhaust pipes 224 and 226. That is, the common gas exhaust pipe 225 is disposed such that the respective process chamber exhaust pipes 224 and 226 join together at downstream sides of the process chamber exhaust pipes 224 and 226. Thus, the process chamber exhaust pipes 224 and 226 join together at a joining part 230 at downstream ends and further connected to the common gas exhaust pipe 225.

An exhaust pump 223 is disposed at the downstream side of the common gas exhaust pipe 225. An auto pressure controller (APC) 222, a valve 221, and valves 228a and 228b are installed between the exhaust pump 223 and the chambers 100a and 100b sequentially from the corresponding downstream sides, respectively. The gas exhaust part includes the APC 222, the valve 221, the valves 228a and 228b, the process chamber exhaust pipes 224 and 226, and the common gas exhaust pipe 225. As described above, the internal atmosphere of the chamber 100a and the internal atmosphere of the chamber 100b are exhausted by one exhaust pump 223.

A pressure detector 227a is installed at the process chamber exhaust pipe 224. The pressure detector 227a detects an internal pressure of the process chamber exhaust pipe 224, and may be configured by using, for example, a pressure sensor. The second inert gas supply pipe 141a is connected to the process chamber exhaust pipe 224 at an upstream side of the pressure detector 227a.

Further, a pressure detector 227b is installed at the process chamber exhaust pipe 226. The pressure detector 227b detects the internal pressure of the process chamber exhaust pipe 226 and may be configured by using, for example, a pressure sensor. The second inert gas supply pipe 141b is connected to the process chamber exhaust pipe 226 at an upstream side of the pressure detector 227b.

One or a combination of the pressure detectors 227a and 227b may be referred to as an exhaust pipe pressure detector.

The process chamber exhaust pipe 224 is configured to include a longitudinal pipe 224a disposed along a longitudinal direction and a lateral pipe 224b disposed along a lateral direction in a state where the substrate processing apparatus 10 is installed. The longitudinal direction described above refers to a vertical direction or a direction inclined by a predetermined allowable inclination angle from the vertical direction. Further, the lateral direction refers to a horizontal direction or a direction inclined by a predetermined allowable inclination angle from the horizontal direction.

A length of the longitudinal pipe 224a is set to a distance at which the inert gas supplied from the second inert gas supply pipe 141a does not affect an atmosphere of a processing space 305 as described below. With this configuration, processing conditions of the processing space 305 (for example, a pressure of the processing space 305) are not affected.

The inert gas supply pipe 141a is connected to the lateral pipe 224b. Therefore, the pressure detector 227a is installed between the second inert gas supply pipe 141a and the joining part 230 in the lateral pipe 224b.

The process chamber exhaust pipe 226 is configured to include a longitudinal pipe 226a disposed along a longitudinal direction and a lateral pipe 226b disposed along a lateral direction in a state where the substrate processing apparatus 10 is installed. The longitudinal direction and the lateral direction are as described above.

A length of the longitudinal pipe 226a is set to a distance at which the inert gas supplied from the second inert gas supply pipe 141b does not affect an atmosphere of a processing space 305 to be described below. With this configuration, processing conditions of the processing space 305 (for example, a pressure of the processing space 305) are not affected.

The inert gas supply pipe 141b is connected to the lateral pipe 226b. Thus, the pressure detector 227b is installed between the second inert gas supply pipe 141b and the joining part 230 in the lateral pipe 226b.

The following effects may be derived by the configuration in which each of the pressure detectors 227a and 227b is installed between the second inert gas supply pipes 141a and 141b and the joining part 230.

According to the aforementioned configuration, a pressure when a mixture of the inert gas supplied from each of the second inert gas supply pipes 141a and 141b and the processing gas exhausted from the processing space 305 by each of the process chamber exhaust pipes 224 and 226 flows may be detected. Thus, at an exhaust regulation step S102 to be described below, more accurate setting is possible.

Further, according to the aforementioned configuration, clogging of the pressure detectors 227a and 227b can be prevented by locating the pressure detectors 227a and 227b at the downstream side of the second inert gas supply pipes 141a and 141b. In a case where the pressure detectors 227a and 227b are installed at the upstream side of a connection point with the inert gas supply pipes 141a and 141b, a concentration of the processing gas exhausted to the process chamber exhaust pipes 224 and 226 is high, which may cause a clogging at the pressure detectors 227a and 227b. On the other hand, in the aforementioned configuration, since the pressure detectors 227a and 227b are installed at the downstream side of the inert gas supply pipes 141a and 141b, it is possible to reduce the concentration of the processing gas, thereby suppressing the occurrence of clogging.

### (Chamber)

Next, a detailed structure of the chambers 100a and 100b in the process module 110 will be described. In the present disclosure, since each of the plurality of chambers 100a and 100b has a similar configuration, one chamber 100a (hereinafter, simply referred to as the chamber 100) will be described as an example.

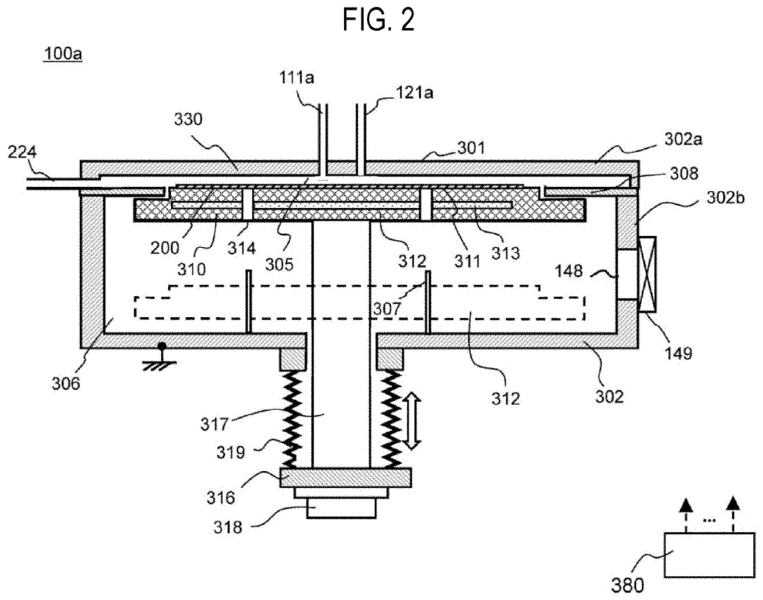

FIG. 2 is a configuration diagram of a chamber of a substrate processing apparatus according to some embodiments of the present disclosure.

The chamber 100 is made of, for example, a metal material such as aluminum (Al) or stainless steel (SUS), and is configured as, for example, a flat sealed vessel 302 having a circular cross section. The sealed vessel 302 includes an upper vessel 302a and a lower vessel 302b, and a partition plate 308 is installed between the upper vessel 302a and the lower vessel 302b. A substrate loading/unloading port 148 is installed adjacent to the gate valve 149 at a side surface of the lower vessel 302b such that the substrate 200 moves to and from a vacuum transfer chamber (not shown) via the substrate loading/unloading port 148. A plurality of lift pins 307 are installed at a bottom of the lower vessel 302b. Further, the lower vessel 302b is grounded.

A substrate support 310 configured to support the substrate 200 is installed in the chamber 100 configured as the sealed vessel 302. The substrate support part 310 mainly includes a substrate mounting surface 311 on which the substrate 200 is mounted, a substrate mounting stand 312 having the substrate mounting surface 311 on its surface, and a heater 313 as a heating source included in the substrate mounting stand 312. Through-holes 314 through which the lift pins 307 pass are respectively formed at positions corresponding to the lift pins 307 in the substrate mounting stand 312.

The substrate mounting stand 312 is supported by a shaft 317. A support of the shaft 317, which penetrates a hole formed at a bottom wall of the chamber 100, is connected to an elevator mechanism 318 outside the chamber 100 via a support plate 316. The substrate 200 mounted on the substrate mounting surface 311 can be raised or lowered by operating the elevator mechanism 318 to move the shaft 317 and the substrate mounting stand 312 up or down. In addition, a periphery of a lower end portion of the shaft 317 is covered with a bellows 319 such that the interior of the chamber 100 is hermetically maintained.

When the elevator mechanism 318 raises the substrate mounting stand 312, the substrate mounting stand 312 is located at a substrate processing position illustrated in the drawing. At the substrate processing position, the lift pins 307 are retreated from an upper surface of the substrate mounting surface 311 such that the substrate mounting surface 311 supports the substrate 200 from below. Further, when the substrate 200 is processed, the substrate mounting stand 312 is maintained at the substrate processing position. Further, when the elevator mechanism 318 lowers the substrate mounting stand 312, the substrate mounting stand 312 is such that the substrate mounting surface 311 is located at a substrate transfer position facing the substrate loading/unloading port 148 (see a dashed line in FIG. 1). At the substrate transfer position, upper end portions of the lift pins 307 protrudes from the upper surface of the substrate mounting surface 311 such that the lift pins 307 support the substrate 200 from below.

The processing space 305 in which the substrate 200 is processed, and a transfer space 306 through which the substrate 200 passes when the substrate 200 is transferred to the processing space 305 are formed in the chamber 100.

The processing space 305 is a space formed between the substrate mounting stand 312 at the substrate processing position and a ceiling 330 of the chamber 100. A structure constituting the processing space 305 will be referred to as a process chamber 301. That is, the processing space 305 is formed in the process chamber 301.

The transfer space 306 is a surface mainly including a lower vessel 302b and a lower structure of the substrate mounting stand 312 at the substrate processing position. A structure constituting the transfer space 306 will be referred to as a transfer chamber. The transfer chamber is disposed below the process chamber 301. Further, the transfer chamber may be any structure as long as the transfer chamber constitutes the transfer space 306, and may not be limited to the aforementioned structure.

A first processing gas supply pipe 111 of the first gas supplier and a second processing gas supply pipe 121 of the second gas supplier are connected to the ceiling 330 facing the processing space 305. More specifically, the first processing gas supply pipe 111a and the second processing gas supply pipe 121a are connected to the ceiling 330 in the chamber 100a, and the first processing gas supply pipe 111b and the second processing gas supply pipe 121b are connected to the ceiling 330 in the chamber 100b. Thus, the first processing gas, the second processing gas, or the inert gas is supplied into the processing space 305.

The process chamber exhaust pipes 224 and 226 of the gas exhaust part are connected to a sidewall portion of the sealed vessel 302 facing the processing space 305. More specifically, the process chamber exhaust pipe 224 is connected to the sidewall portion of the sealed vessel 302 in the chamber 100a, and the process chamber exhaust pipe 226 is connected to the sidewall portion of the sealed vessel 302 in the chamber 100b. Thus, the gas supplied into the processing space 305 is exhausted via the process chamber exhaust pipes 224 and 226.

### (Controller)

The substrate processing apparatus 10 includes a controller 380 as a control part (control means) configured to control operations of the respective parts of the substrate processing apparatus 10.

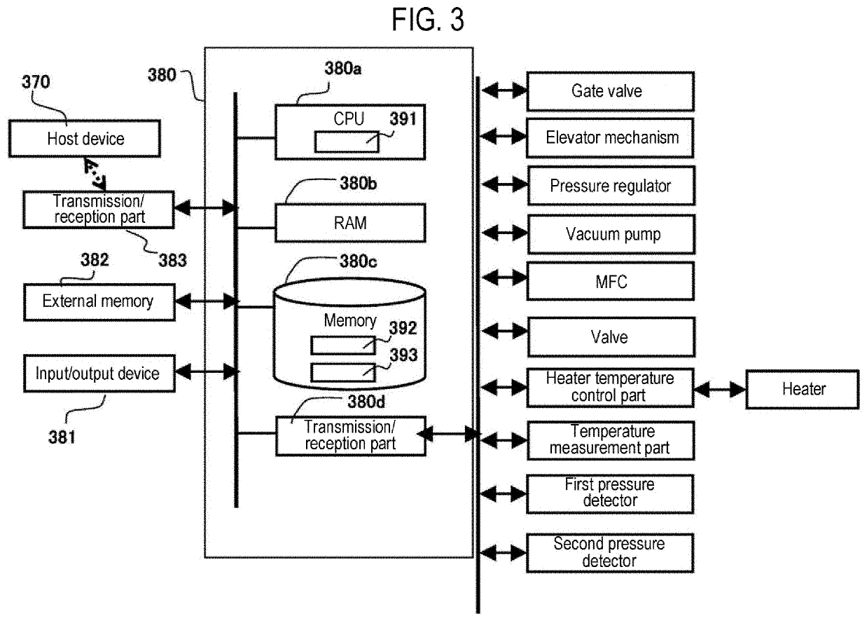

FIG. 3 is a configuration diagram of a controller of a substrate processing apparatus according to some embodiments of the present disclosure.

The controller 380 is constituted as a computer including at least an operation part (CPU) 380a, a temporary memory (RAM) 380b, a memory 380c, and a transmission/reception part 380d. The controller 380 is connected to each of the components of the substrate processing apparatus 10 via the transmission/reception part 380d, and calls a program or a recipe from the memory 380c according to an instruction of a host device 370 connected via a transmission/reception part 383 or a user operating an input/output device 381 and controls the operations of the respective components according to contents of the program or the recipe.

The operation part 380a has a function as a regulator 391. The memory 380c has functions as a pressure data storage 392 and a control data storage 393.

The regulator 391 serves to control the supply of the inert gas from the second inert gas supply pipes 141a and 141b of the fourth gas supplier (second inert gas supplier) based on states of pressures of the gas exhaust part detected by the pressure detectors 227a and 227b. Specifically, the regulator 391 is configured to set control data for the gas supply by the fourth gas supplier according to stored data by referring to the stored data in the pressure data storage 392, and store the set control data in the control data storage 393.

The pressure data storage 392 serves to store detection results (for example, pressure values) by the pressure detectors 227a and 227b.

The control data storage 393 is configured to store control data that controls the gas supply by the fourth gas supplier (second inert gas supplier). The control data is, for example, a control parameter of the MFCs 145a and 145b, or a parameter that controls a degree of opening of the valves 146a and 146b.

Further, the controller 380 may be configured as a dedicated computer or a general-purpose computer. For example, the controller 380 according to the embodiments may be configured by installing, on the general-purpose computer, the aforementioned program stored in an external memory 382 (for example, a magnetic tape, a magnetic disc such as a flexible disc or a hard disk, an optical disc such as a CD or DVD, a magneto-optical disc such as an MO, or a semiconductor memory such as a USB memory (USB flash drive) or a memory card).

Further, means to supply the program to the computer is not limited to the case of supplying the program via the external memory 382. For example, the program may be supplied to the computer by using a communication means such as the Internet or a dedicated line, or the program may be supplied by receiving information from the host device 370 via the transmission/reception part 383, instead of using the external memory 382. Further, the controller 380 may be instructed by using an input/output device 381 such as a keyboard or a touch panel.

Further, the memory 380c or the external memory 382 is configured as a computer-readable recording medium. Hereinafter, the memory 380c and the external memory 382 will be generally and simply referred to as a “recording medium.” When the term “recording medium” is used herein, it may indicate a case of including only the memory 380c, a case of including only the external memory 382, or a case of including both the memory 380c and the external memory 382.

### (2) Sequence of Substrate Processing

Next, a sequence of substrate processing performed by using the substrate processing apparatus 10 of the aforementioned configuration will be described. The substrate processing is performed as a process of manufacturing a semiconductor device, and performs a predetermined process on a wafer 200 to be processed. In the following description, as the predetermined process, examples in which a film is formed on a surface of the wafer 200 by using a DCS gas as a first processing gas and an O₂ gas as a second processing gas will be described. It is assumed herein that an alternating supply process of alternately supplying different processing gases is performed.

When the term “wafer” is used herein, it may refer to a wafer itself or a laminated body of a wafer and a predetermined layer or film formed on the surface of the wafer. Further, when the phrase “a surface of a wafer” is used herein, it may refer to a surface of a wafer itself or a surface of a predetermined layer or the like formed on a wafer. Further, in the present disclosure, the expression “a predetermined layer is formed on a wafer” may mean that a predetermined layer is directly formed on a surface of a wafer itself or that a predetermined layer is formed on a layer or the like formed on a wafer. When the term “substrate” is used herein, it may be synonymous with the term “wafer.”

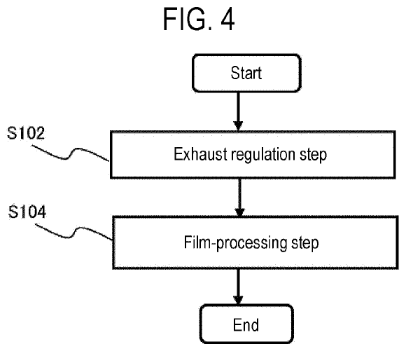

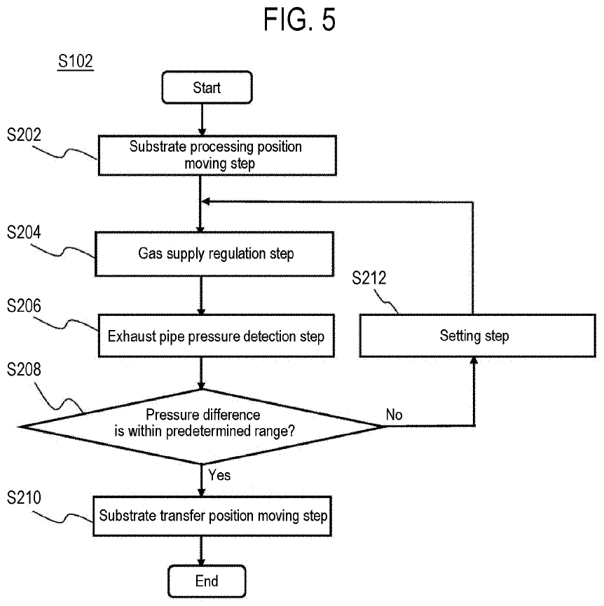

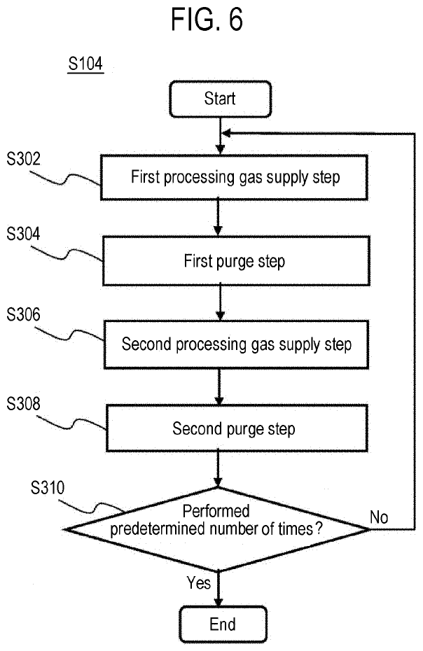

Hereinafter, the substrate processing will be described with reference to FIGS. 4, 5 and 6. FIG. 4 illustrates an overall procedure of the substrate processing. FIG. 5 illustrates details of an exhaust regulation step S102 in the substrate processing. FIG. 6 illustrates details of a film-processing step S104 in the substrate processing.

Further, in the following descriptions, the operations of the respective parts constituting the substrate processing apparatus 10 are controlled by the controller 380.

As illustrated in FIG. 4, in the substrate processing, the exhaust regulation step S102 and the film-processing step S104 are performed. The respective steps will be sequentially described below.

### (Exhaust Regulation Step: S102)

First, the reason why the exhaust regulation step S102 is performed will be described.

The substrate processing apparatus 10 used in the processes of manufacturing a semiconductor device is configured by mounting various components. Therefore, individual differences in performance of the substrate processing apparatus 10 may occur according to an accuracy of processing, assembling, or the like of the components. Specifically, for example, a diameter of the process chamber exhaust pipe 224 and a diameter of the process chamber exhaust pipe 226 may be different. Further, for example, a distance from the chamber 100a to the joining part 230 and a distance from the chamber 100b to the joining part 230 may be different.

As in the embodiments, in the case of the configuration in which the substrate processing apparatus 10 includes the plurality of chambers 100a and 100b and the gas exhaust part (specifically, the common gas exhaust pipe 225, the exhaust pump 223, or the like) is shared by the respective chambers 100a and 100b, when individual differences occur in performance of the components relating to the exhaust flow rate control, an exhaust balance may be broken between the chambers 100a and 100b, causing an exhaust gas to flow back into the respective process chamber 301. The aforementioned exhaust balance indicates that a balance of exhaust states of the respective process chamber exhaust pipes 224 and 226 is good, for example, that the pressures of the respective process chamber exhaust pipes 224 and 226 are substantially equal to each other.

When the exhaust balance is broken, the pressure of each processing space 305 may also vary, lowering a productivity. Specifically, for example, when the pressure of the process chamber exhaust pipe 224 is higher than the pressure of the process chamber exhaust pipe 226, the gas flowing through the process chamber exhaust pipe 224 interrupts a gas flow in the process chamber exhaust pipe 226, thereby breaking an exhaust balance. Therefore, in the embodiments, by performing the exhaust regulation step S102, the exhaust balance between the chambers 100a and 100b is controlled to be good.

Next, details of the exhaust regulation step S102 will be described with reference to FIG. 5. Further, during the exhaust regulation step S102, it is assumed that the pump 223 is continuously activated. Further, it is assumed that an opening degree of the APC 222 is regulated such that the processing space 305 has a desired pressure.

### (Substrate Processing Position Moving Step: S202)

A substrate processing position moving step S202 will be described.

At the substrate processing position moving step S202 performed first at the exhaust regulation step S102, the substrate mounting stand 312 in each of the chambers 100a and 100b is moved to the substrate processing position in a state in which there is no substrate 200 on the substrate mounting surface 311 or a dummy substrate as a dummy product of the substrate 200 is mounted on the substrate mounting surface 311. Thus, the same exhaust conditions as those of a film-processing step S104 to be described below are set in each of the chambers 100a and 100b.

### (Gas Supply Regulation Step: S204)

A gas supply regulation step S204 will be described.

At the gas supply regulation step S204, after the substrate mounting stand 312 is moved to the substrate processing position at the substrate processing position moving step S202, the gas supply to the processing space 305 of each of the chambers 100a and 100b starts. At this step, a processing gas or an inert gas is supplied to the processing space 305. Further, after a setting step S212 to be described below, control data that is used to control the fourth gas supplier (second inert gas supplier) is read from the control data storage 393, and the inert gas is supplied to the process chamber exhaust pipes 224 and 226 while performing the gas supply control based on the control data.

At this time, the gas supply to the processing space 305 may be performed under the same conditions as those of the film-processing step S104 to be described below. For example, the processing gas (for example, a DCS gas or an O₂ gas) supplied at the film-processing step S104 is supplied. Further, the heater 313 may be heated in the same manner as the film-processing step S104 to be brought closer to a temperature condition of the film-processing step S104. Such processes are particularly effective when an exhaust situation changes depending on characteristics of the gas, such as a degree of decomposition or viscosity of gas.

### (Exhaust Pipe Pressure Detection Step: S206)

An exhaust pipe pressure detection step S206 will be described.

At the exhaust pipe pressure detection step S206, an internal pressure of the process chamber exhaust pipe 224 is detected by the pressure detector 227a and an internal pressure of the process chamber exhaust pipe 226 is detected by the pressure detector 227b while supplying the gas to the processing space 305 at the gas supply regulation step S204. Then, each detection result (for example, a pressure value in a pipe) by each of the pressure detectors 227a and 227b is stored in the pressure data storage 392 of the controller 380.

### (Determination Step: S208)

A determination step S208 will be described.

At the determination step S208, the regulator 391 reads pressure detection results of the process chamber exhaust pipes 224 and 226 by referring to the pressure data storage 392. Then, it is determined whether a pressure difference between the pressure detection results falls within a predetermined range. That is, the regulator 391 determines whether the pressure difference between the process chamber exhaust pipes 224 and 226 is smaller than a predetermined threshold value (hereinafter, referred to as a first threshold). If the pressure difference falls within the predetermined range, it is determined that there is no pressure variation to the extent that it affects the substrate processing at the film-processing step S104 to described below, and the process goes to execution of a substrate transfer position moving step S210 subsequently described. On the other hand, if the pressure difference does not fall within the predetermined range, that is, if the pressure difference is equal to or larger than the first threshold value, the process returns to the gas supply regulation step S204 via the setting step S212 to be described below.

### (Substrate Transfer Position Moving Step: S210)

A substrate transfer position moving step S210 will be described.

If it is determined to be “Yes” (that is, if the pressure difference falls within the predetermined range) at the determination step S208, then the substrate mounting stand 312 in each of the chambers 100a and 100b is moved to the substrate transfer position in preparation for loading the substrate 200 at the film-processing step S104 subsequently performed.

### (Setting Step: S212)

The setting step S212 will be described. The setting step S212 is a step of setting the control data that is used to control the fourth gas supplier (second inert gas supplier).

As already described above, if the pressure difference between the process chamber exhaust pipes 224 and 226 does not fall within the predetermined range, the exhaust balance between the chambers 100a and 100b may be broken. In that case, the supply of the inert gas from the second inert gas supply pipes 141a and 141b in the fourth gas supplier (second inert gas supplier) may be properly regulated such that the pressure difference between the process chamber exhaust pipes 224 and 226 is controlled to be converged within the predetermined range, thereby improving the exhaust balance. The supply of the inert gas from the second inert gas supply pipes 141a and 141b may be regulated by respectively controlling the valves 146a and 146b and the MFCs 145a and 145b by the controller 380.

Therefore, at the setting step S212, the regulator 391 properly sets the control data that is used to control the fourth gas supplier (second inert gas supplier) depending on the pressure difference between the process chamber exhaust pipes 224 and 226, whereby the exhaust balance between the chambers 100a and 100b is improved. For example, if the pressure of the process chamber exhaust pipe 224 is higher than that of the process chamber exhaust pipe 226, the control data that is used to control the MFCs 145a and 145b, the valves 146a and 146b, or the like is set such that the pressure of the process chamber exhaust pipe 226 is increased by a differential pressure by supplying the inert gas from the second inert gas supply pipe 141b to the process chamber exhaust pipe 226. By controlling the supply of the inert gas by the fourth gas supplier based on such control data, the pressure difference between the process chamber exhaust pipes 224 and 226 is reduced to be converged within the predetermined range, whereby it becomes possible to improve the exhaust balance between the chambers 100a and 100b.

That is, the regulator 391 sets the control data that is used to control the fourth gas supplier (second inert gas supplier) based on the states of the pressures detected by the pressure detectors 227a and 227b. Further, the regulator 391 stores the set control data in the control data storage 393, whereby the stored data may be used at the gas supply regulation step S204 or the film-processing step S104 subsequently performed. In this manner, the regulator 391 may control the supply of the inert gas from the second inert gas supply pipes 141a and 141b to the process chamber exhaust pipes 224 and 226.

A form of controlling the inert gas supply at this time is not particularly limited as long as the pressure difference between the process chamber exhaust pipes 224 and 226 may be reduced to equalize the respective pressures. For example, the inert gas may be controlled to be supplied to either of the process chamber exhaust pipes 224 and 226 or may be controlled to be supplied to both the process chamber exhaust pipes 224 and 226 at different pressures, depending on the pressure difference between the process chamber exhaust pipes 224 and 226.

The exhaust balance between the chambers 100a and 100b is improved at the exhaust regulation step S102 before the film-processing step S104 by going through the series of steps S202 to S212 described above.

At that time, at the exhaust regulation step S102, the state is set such that the substrate 200 does not exist on the substrate mounting surface 311 or the dummy substrate is mounted on the substrate mounting surface 311, as already described above. The reason will be described below.

For example, it is assumed that the exhaust regulation step S102 is performed while the substrate 200 which is a product substrate is mounted on a substrate mounting surface 311. In that case, when regulating the inert gas, the processing gas collides with the inert gas, and as a result, the processing gas may flow back into the processing space 305. In a case where such a backflow of the processing gas occurs, an extra film may be formed on the substrate 200 which is the product substrate, lowering the productivity.

On the other hand, as described in the embodiments, when the exhaust regulation step S102 is performed without the substrate 200 or with the dummy substrate mounted, the processing on the substrate 200 as the product substrate is not affected even when the backflow of the processing gas occurs, whereby high productivity may be maintained.

Further, the exhaust regulation step S102 may be performed under the same conditions as those of the film-processing step S104 in some embodiments. As described in detail below, the film-processing step S104 includes a first processing gas supply step S302, a first purge step S304, a second processing gas supply step S306, and a second purge step S308. Further, since the atmosphere of the processing space 305 is changed at each of steps S302 to S308, the gas supply conditions are changed at each step. For example, the pressure of the processing space 305 at each of steps S302 to S308 may be different.

Therefore, at the exhaust regulation step S102, steps corresponding to the first processing gas supply step S302, the first purge step S304, the second processing gas supply step S306, and the second purge step S308 may be performed. Specifically, at each corresponding step, the pressure detector 227 detects the pressure of each of the process chamber exhaust pipes 224 and 226, and the regulator 391 sets the control data that is used to control the fourth gas supplier (second inert gas supplier).

Then, the set control data is stored in the control data storage 393 for each step, that is, for each of the first processing gas supply step S302, the first purge step S304, the second processing gas supply step S306, and the second purge step S308.

### (Film-Processing Step: S104)

Next, the film-processing step S104 will be described.

At the film-processing step S104, the substrate 200 which is the product substrate is loaded into the chamber 100, and the substrate 200 is processed by supplying a gas from the gas supplier. After the processing is completed, the substrate 200 is unloaded from the interior of the chamber 100. This operation is repeatedly performed on a predetermined number of substrates 200. Details of such film-processing step S104 are discussed below.

Meanwhile, the internal pressure of the process chamber exhaust pipe 224 may be detected by the pressure detector 227a, the internal pressure of the process chamber exhaust pipe 226 may be detected by the pressure detector 227b, and each detection result may be stored in the pressure data storage 392 in the same manner as at the exhaust regulation step S102, even while the film-processing step S104 is performed, in some embodiments.

Further, when the pressure difference between the pressure detection results of the respective pressure detectors 227a and 227b does not fall within the predetermined range, the same processing operation as that of the exhaust regulation step S102 may be performed in some embodiments. Within the predetermined rage mentioned herein is determined by whether the pressure difference is smaller than a predetermined threshold value (hereinafter, referred to as a second threshold value).

The reasons are described below.

When the film-processing step S104 is performed, a film may be deposited in the process chamber exhaust pipes 224 and 226. The reason is that the temperature of the process chamber exhaust pipes 224 and 226 is lower than that of the processing space 305, or the pressure becomes higher since the process chamber exhaust pipes 224 and 226 are narrower than the processing space 305.

The thicknesses of the films deposited in the process chamber exhaust pipes 224 and 226 vary depending on a difference in entities and the like of the components relating to the chambers 100a and 100b to which the process chamber exhaust pipes 224 and 226 are respectively connected. In a case where the film thickness is large, the internal pressure of each of the process chamber exhaust pipes 224 and 226 may also be affected, but in the case where the film thickness is different in each of the process chamber exhaust pipes 224 and 226, an exhaust balance may be broken.

Therefore, a processing operation in which the control data that is used to control the fourth gas supplier (second inert gas supplier) is reset and stored in the control data storage 393 may be performed when the internal pressure of the process chamber exhaust pipe 224 is detected by the pressure detector 227a, the internal pressure of the process chamber exhaust pipe 226 is detected by the pressure detector 227b, and the pressure difference between the respective detection results does not fall within the predetermined range, not only while the exhaust regulation step S102 described above is performed and but also while the film-processing step S104 is performed.

### (Details of Film-Processing Step S104)

Subsequently, details of the film-processing step S104 will be described with reference to FIG. 6.

### (Substrate Loading/Mounting Step)

At the film-processing step S104, first, a substrate loading/mounting step is performed. In FIG. 6, this step is not illustrated.

At the substrate loading/mounting step, the substrate mounting stand 312 in the chamber 100 is lowered to a substrate loading position, and the lift pins 307 pass through the through-holes 314 of the substrate mounting stand 312. Thus, the lift pins 307 protrude from the surface of the substrate mounting stand 312 by a predetermined height. Then, in that state, the gate valve 149 is opened such that the transfer space 306 becomes in fluid communication with the vacuum transfer chamber (not shown), and the substrate 200 is loaded from the vacuum transfer chamber into the transfer space 306 by a substrate transfer device (not shown), and the substrate 200 is transferred onto the lift pins 307. Thus, the substrate 200 is supported in a horizontal posture on the lift pins 307 protruding from the surface of the substrate mounting stand 312.

When the substrate 200 is loaded into the chamber 100, the substrate transfer device is retreated to the outside of the chamber 100, and the interior of the chamber 100 is sealed by closing the gate valve 149. Thereafter, the substrate mounting stand 312 is raised to mount the substrate 200 on the substrate mounting surface 311, and the substrate mounting stand 312 is raised to the substrate processing position to locate the substrate 200 on the substrate mounting surface 311 within the processing space 305.

At this time, electric power is supplied to the heater 313 embedded in the substrate mounting stand 312, and the surface of the substrate 200 on the substrate mounting surface 311 is controlled to have a predetermined temperature. The temperature of the substrate 200 may be, for example, a room temperature or higher and 800 degrees C. or lower, specifically, a room temperature or higher and 500 degrees C. or lower in some embodiments. At that time, the temperature of the heater 313 may be regulated by extracting a control value and controlling a state of supplying electric power to the heater 313 by the controller 380 based on temperature information detected by a temperature sensor (not shown).

It is assumed that the processing operations described above are similarly performed in each of the chambers 100a and 100b.

### (First Processing Gas Supply Step: S302)

The first processing gas supply step S302 will be described.

When the substrate 200 in the processing space 305 reaches a predetermined temperature, first, the first processing gas supply step S302 is performed. At the first processing gas supply step S302, the valves 116a and 116b are opened, and the MFC 115a and 115b are regulated such that the DCS gas has a predetermined flow rate. Further, the supply flow rate of the DCS gas is, for example, 100 sccm or more and 800 sccm or less. At this time, a N₂ gas is supplied from the third gas supplier. The N₂ gas supplied from the third gas supplier is used as a carrier gas of the DCS gas.

In addition, at the first processing gas supply step S302, the valves 221, 228a and 228b are opened, and the opening degree of the APC 222 is regulated while activating the pump 223 such that the interior of the chamber 100 has a desired pressure. Specifically, the pressure of each of the processing space 305 and the transfer space 306 is controlled to have a predetermined value of, for example, 50 to 300 Pa. The predetermined value may be set to, for example, 250 Pa.

At this time, based on the control data stored in the control data storage 393, the MFCs 145a and 145b are regulated, while the valves 146a and 146b are opened, such that the flow rate of the inert gas supplied from the second inert gas supply pipes 141a and 141b becomes a predetermined flow rate. In reading the control data from the control data storage 393, in a case where the control data is calculated and set by performing a step corresponding to the first processing gas supply step S302 at the exhaust regulation step S102, it is assumed that the control data corresponding to the first processing gas supply step S302 is read.

By such processing operation, the inert gas is supplied to either or both of the process chamber exhaust pipe 224 and the process chamber exhaust pipe 226, and the pressure difference between the process chamber exhaust pipes 224 and 226 is reduced to have substantially the same pressure. Thus, it is possible to suppress the exhaust balance between the chambers 100a and 100b from being broken at this step.

In the processing space 305 to which the DCS gas is supplied, the DCS gas is decomposed into silicon components or the like by heat and supplied to the substrate 200. Thus, a silicon-containing layer as a “first element-containing layer” is formed on the surface of the substrate 200. The silicon-containing layer corresponds to a precursor of a thin film to be formed.

After the lapse of a predetermined period of time from the start of this step, the valves 116a and 116b are closed to stop the supply of the DCS gas. Specifically, when the supply of the DCS gas is stopped, the supply of the inert gas from the fourth gas supplier (second inert gas supplier) may also be stopped in synchronization with the stop of the supply of the DCS gas in some embodiments. According to such a synchronous stop, it is possible to prevent particles in the process chamber exhaust pipes 224 and 226 from flowing back to the processing space 305.

### (First Purge Step: S304)

The first purge step S304 will be described.

After the completion of the first processing gas supply step S302, the first purge step S304 is then performed. At the first purge step S304, the opening states of the valves 136a, 136b, 176a and 176b are maintained, and the valves 186a and 186b are opened to continue the exhaust by the pump 223 or the like while supplying the N₂ gas to the processing space 305. Thus, the atmosphere is purged.

In addition, at the first purge step S304, based on the control data stored in the control data storage 393, the MFCs 145a and 145b are regulated, while the valves 146a and 146b are opened, such that the flow rate of the inert gas supplied from the second inert gas supply pipes 141a and 141b becomes the predetermined flow rate. In reading the control data from the control data storage 393, in a case where the control data is calculated and set by performing a step corresponding to the first purge step S304 at the exhaust regulation step S102, it is assumed that the control data corresponding to the first purge step S304 is read.

By such processing operations, the inert gas is supplied to either or both of the process chamber exhaust pipe 224 and the process chamber exhaust pipe 226, and the pressure difference between the respective process chamber exhaust pipes 224 and 226 is reduced to have substantially the same pressure. Thus, it is possible to suppress the exhaust balance between the chambers 100a and 100b from being broken at this step.

After a predetermined period of time elapses from the start of this step, the valves 136a and 136b are closed to stop the purge of the atmosphere by the supply of the N₂ gas. Specifically, when the supply of the N₂ gas is stopped, the supply of the inert gas from the fourth gas supplier (second inert gas supplier) may also be stopped in synchronization with the stop of the supply of the N₂ gas. According to such a synchronous stop, it is possible to prevent particles in the process chamber exhaust pipes 224 and 226 from flowing back to the processing space 305.

### (Second Processing Gas Supply Step: S306)

The second processing gas supply step S306 will be described.

When the valve valves 136a and 136b are closed to terminate the first purge step S304, the second processing gas supply step S306 is then performed. At the second processing gas supply step S306, the valves 126a and 126b are opened and the flow rate regulation is performed by the MFCs 125a and 125b to start the supply of an O₂ gas into the processing space 305. A supply flow rate of the 02 gas may be, for example, 100 sccm or more and 6,000 sccm or less. At this time, the N₂ gas is supplied from the third gas supplier. The N₂ gas supplied from the third gas supplier is used as a carrier gas or a dilution gas of the 02 gas.

Further, at the second processing gas supply step S306, the exhaust by the pump 223 or the like may be continued such that the interior of the chamber 100 has a desired pressure, as at the first processing gas supply step S302. Then, based on the control data stored in the control data storage 393, the MFCs 145a and 145b are regulated, while the valves 146a and 146b are opened, such that the flow rate of the inert gas supplied from the second inert gas supply pipes 141a and 141b becomes a predetermined flow rate. In reading the control data from the control data storage 393, when the control data is calculated and set by performing a step corresponding to the second processing gas supply step S306 at the exhaust regulation step S102, it is assumed that the control data corresponding to the second processing gas supply step S306 is read.

By such processing operations, the inert gas is supplied to either or both of the process chamber exhaust pipe 224 and the process chamber exhaust pipe 226, and the pressure difference between the respective process chamber exhaust pipes 224 and 226 is reduced to have substantially the same pressure. Thus, it is possible to suppress the exhaust balance between the chambers 100a and 100b from being broken at this step.

The 02 gas supplied to the processing space 305 becomes a plasma state by at least one selected from the group of RPUs 124, 124a and 124b. In the processing space 305 to which the 02 gas in the plasma state is supplied, the 02 gas is supplied to the substrate 200. Thus, the silicon-containing layer is modified with the 02 gas to form a thin film formed of a layer containing a silicon element and an oxygen element on the surface of the substrate 200.

After a predetermined period of time elapses from the start of this step, the valves 126a and 126b are closed to stop the supply of the 02 gas. Specifically, when the supply of the 02 gas is stopped, the supply of the inert gas from the fourth gas supplier (second inert gas supplier) may also be stopped in synchronization with the stop of the supply of the 02 gas in some embodiments. According to such a synchronous stop, it is possible to prevent particles in the process chamber exhaust pipes 224 and 226 from flowing back to the processing space 305.

### (Second Purge Step: S308)

The second purge step S308 will be described.

After the second processing gas supply step S306 is completed, the second purge step S308 is then performed. At the second purge step S308, the N₂ gas is supplied from the first inert gas supply pipes 131a and 131b as at the first purge step S304. Thus, the atmosphere of the processing space 305 is purged.

Further, at the second purge step S308, based on the control data stored in the control data storage 393, the MFCs 145a and 145b are regulated, while the valves 146a and 146b are opened, such that the flow rate of the inert gas supplied from the second inert gas supply pipes 141a and 141b becomes a predetermined flow rate. In reading the control data from the control data storage 393, when the control data is calculated and set by performing a step corresponding to the second purge step S308 at the exhaust regulation step S102, it is assumed that the control data corresponding to the second purge step S306 is read.

By such processing operations, the inert gas is supplied to either or both of the process chamber exhaust pipe 224 and the process chamber exhaust pipe 226, and the pressure difference between the process chamber exhaust pipes 224 and 226 is reduced to have substantially the same pressure. Thus, it is possible to suppress the exhaust balance between the chambers 100a and 100b from being broken at this step.

After a predetermined period of time elapses from the start of this step, the valves 136a and 136b are closed to stop the purge of the atmosphere by the supply of the N₂ gas. Specifically, when the supply of the N₂ gas is stopped, the supply of the inert gas from the fourth gas supplier (second inert gas supplier) may also be stopped in synchronization with the stop of the supply of the N₂ gas in some embodiments. According to such a synchronous stop, it is possible to prevent particles in the process chamber exhaust pipes 224 and 226 from flowing back to the processing space 305.

### (Determination Step: S310)

A determination step S310 will be described.

When the second purge step S308 is completed, the controller 380 determines whether a cycle has been performed a predetermined number of times (n cycle), the cycle including sequentially performing: the first processing gas supply step S302; the first purge step S304; the second processing gas supply step S306; and the second purge step S308.

In a case where the cycle has not been performed the predetermined number of times (when “No” at S310), the cycle including sequentially performing the first processing gas supply step S302, the purge step S304, the second processing gas supply step S306, and the purge step S308 is repeated. In a case where the cycle has been performed the predetermined number of times (when “Yes” at S310), the series of processes illustrated in FIG. 6 are completed.

### (Substrate Unloading Step)

Then, a substrate unloading step is performed. Further, this step is not illustrated in FIG. 6.

At the substrate unloading step, the substrate mounting stand 312 in the chamber 100 is lowered to the substrate transfer position such that the substrate 200 is supported on the lift pins 307 protruding from the surface of the substrate mounting stand 312. Thus, the substrate 200 is transferred from the substrate processing position to the substrate transfer position. Then, in that state, the gate valve 149 is opened and the substrate 200 is unloaded to the outside of the chamber 100 by using the substrate transfer device (not shown).

### (3) Effects According to the Embodiments

According to the embodiments of the present disclosure, one or more effects as set forth below may be achieved.

(a) According to the embodiments of the present disclosure, the second inert gas supply pipes 141a and 141b are respectively connected to the plurality of process chamber exhaust pipes 224 and 226 such that the inert gas is supplied from the second inert gas supply pipes 141a and 141b into the corresponding pipes of the process chamber exhaust pipes 224 and 226. This makes it possible to suppress the exhaust balance between the chambers 100a and 100b from being broken by reducing the pressure difference between the process chamber exhaust pipes 224 and 226. Thus, even when the plurality of chambers 100a and 100b are included, it is possible to improve the exhaust balance between the chambers 100a and 100b, and as a result, to maintain high productivity.

(b) According to the embodiments of the present disclosure, the pressure detectors 227a and 227b are respectively installed at the plurality of process chamber exhaust pipes 224 and 226. Therefore, since the pressure difference between the process chamber exhaust pipes 224 and 226 may be properly detected, which is very useful in improving the exhaust balance between the chambers 100a and 100b.

(c) According to the embodiments of the present disclosure, the supply of the inert gas from the second inert gas supply pipes 141a and 141b into the corresponding pipes of the process chamber exhaust pipes 224 and 226 is controlled based on the states of the pressures detected by the pressure detectors 227a and 227b. Therefore, the pressure difference between the process chamber exhaust pipes 224 and 226 may be reliably reduced to have substantially the same pressure, which is very useful in improving the exhaust balance between the chambers 100a and 100b.

(d) According to the embodiments of the present disclosure, the second inert gas supply pipes 141a and 141b are connected to the process chamber exhaust pipes 224 and 226 at the upstream sides of detection positions of the pressure detectors 227a and 227b respectively. Since the pressure when a mixture of the processing gas and the inert gas flows may be detected, accurate setting may be performed at the exhaust regulation step S102. Further, it is possible to prevent clogging of the pressure detectors 227a and 227b.

(e) According to the embodiments of the present disclosure, the process chamber exhaust pipes 224 and 226 include the longitudinal pipes 224a and 226a and the lateral pipes 224b and 226b respectively, and the second inert gas supply pipes 141a and 141b are connected to the lateral pipes 224b and 226b respectively. Thus, the pressure detectors 227a and 227b are respectively installed between the second inert gas supply pipes 141a and 141b and the joining part 230, and the second inert gas supply pipes 141a and 141b are respectively connected to the upstream sides of the pressure detectors 227a and 227b. This also enables accurate setting at the exhaust regulation step S102 and can prevent clogging of the pressure detectors 227a and 227b.

(f) According to the embodiments of the present disclosure, the inert gas is supplied from the second inert gas supply pipes 141a and 141b is performed such that the pressure difference between the plurality of process chamber exhaust pipes 224 and 226 falls within the predetermined range. That is, by suppressing the pressure difference between the process chamber exhaust pipes 224 and 226 to within the predetermined range, it is possible to suppress the exhaust balance between the chambers 100a and 100b from being broken, which is very useful in improving the exhaust balance between the chambers 100a and 100b.

### Other Embodiments

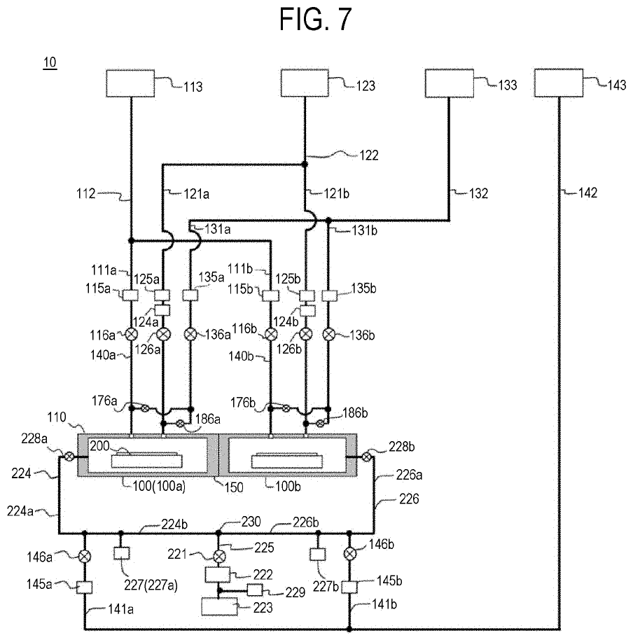

Next, other embodiments of the present disclosure will be described with reference to FIG. 7.

FIG. 7 is a schematic configuration diagram of a substrate processing apparatus according to other embodiments of the present disclosure.

A difference from the aforementioned embodiments is that a pressure detector 229 is installed at a common gas exhaust pipe 225, and that contents of an exhaust pipe pressure detection step S206, a determination step S208, and a setting step S212 are different from those in the aforementioned embodiments, but other matters are similar to those in the aforementioned embodiments. The differences will be mainly described below.

In these embodiments of the present disclosure, the pressure detector 229 is installed in the common gas exhaust pipe 225. The pressure detector 229 may be installed at the downstream side of the APC 222, that is, between the APC 222 and the pump 223 in some embodiments.

The pressure detector 229 functions as a joining pipe pressure detector configured to detect the internal pressure of the common gas exhaust pipe 225, and may be configured by using, for example, a pressure sensor, as in pressure detectors 227a and 2227b. That is, the pressure detector 229 as the joining pipe pressure detector, which is a portion of the pressure detectors, is installed at the common gas exhaust pipe 225. Hereinafter, the pressure detector 229 will be referred to as the joining pipe pressure detector. One or a combination of the pressure detector 227a, the pressure detector 227b, and the pressure detector 229 may be referred to as an exhaust pipe pressure detector.

In a case where the pressure detector 229 is installed such that the pressure at the downstream side of the APC 222 may be detected in this way, when the pressure detector 229 detects a value significantly different from a predetermined normal detection value, it is possible to determine that the APC 222 is damaged or any abnormality occurs in the exhaust pipe 224, the exhaust pipe 226, or the like. The detection value detected by the pressure detector 229 is stored in the pressure data storage 392.

Then, the exhaust pipe pressure detection step S206, the determination step S208, and setting step S212 according to these embodiments of the present disclosure will be described.

### (Exhaust Pipe Pressure Detection Step: S206)

The exhaust pipe pressure detection step S206 will be described.

At the exhaust pipe pressure detection step S206, a pressure at the common gas exhaust pipe 225 is detected by the pressure detector 229, in addition to detecting the internal pressure of the exhaust pipe 224 by the pressure detector 227a and detecting the internal pressure of the exhaust pipe 226 by the pressure detector 227b, while the gas is supplied to the processing space 305. Then, detection results (for example, a pressure value in the pipe) by the respective pressure detectors 227a, 227b, and 229 are stored in the pressure data storage 392.

### (Determination Step: S208)

The determination step S208 will be described.

At the determination step S208, the regulator 391 reads pressure detection results by the pressure detector 227a and the pressure detector 229 by referring to the pressure data storage 392, and calculates a pressure difference between the pressure detection results. Such a pressure difference is a pressure difference of a left side portion in FIG. 7, and is expressed as APL.

Similarly, the regulator 391 reads the pressure detection results by the pressure detector 227b and the pressure detector 229 by referring to the pressure data storage 392, and calculates the pressure difference between the pressure detection results. Such a pressure difference is a pressure difference of a right side portion in FIG. 7, and is expressed as ΔPR.

Subsequently, the regulator 391 determines whether a difference between the pressure difference ΔPL and the pressure difference ΔPR falls within a predetermined range. That is, the regulator 391 determines whether the difference between the pressure differences ΔPL and ΔPR is smaller than a predetermined threshold value (hereinafter, referred to as a third threshold value). When the difference falls within the predetermined range, it is determined that there is no pressure variation which may affect the substrate processing at the film-processing step S104, and the process proceeds to execute the substrate transfer position moving step S210. On the other hand, when the difference does not fall within the predetermined range, that is, when the difference between the pressure differences ΔPL and ΔPR is equal to or larger than the third threshold value, the process returns to the setting step S212.

### (Setting Step: S212)

The setting step S212 will be described. At this step, the control data that is used to control the fourth gas supplier (second inert gas supplier) is set.

The regulator 391 sets the control data that is used to control the fourth gas supplier depending on the difference between the pressure differences ΔPL and ΔPR to reduce the pressure difference between the process chamber exhaust pipes 224 and 226 such that the internal pressure of the process chamber exhaust pipe 224 and the internal pressure of the process chamber exhaust pipe 226 are equalized. Then, the set control data is stored in the control data storage 393.

Then, at the film-processing step S104, the substrate 200 is processed by controlling the fourth gas supplier based on the set control data.

### Effects According to these Embodiments

According to these embodiments of the present disclosure, effects as set forth below may be further achieved in addition to the effects of the aforementioned embodiments of the present disclosure.

According to theses embodiments of the present disclosure, by installing the pressure detector 229 at the common gas exhaust pipe 225, it is possible to easily detect an abnormality of components at the corresponding upstream side. Further, by detecting the difference between the pressure difference ΔPL of the pressure detector 227a and the pressure detector 229 and the pressure difference ΔPR of the pressure detector 227b and the pressure detector 229, it is possible to more accurately detect an abnormality of the chamber 100a or 100b.

### Other Embodiments

Next, other embodiments of the present disclosure will be described.

A difference from the aforementioned embodiments is that the pressure data storage 392 stores history information. The difference will be mainly described below.

In these embodiments, the pressure data storage 392 stores the detection result of the pressure detector as the history information. The history information corresponds to the results previously detected by the pressure detectors, and may correspond to those detected by the pressure detectors 227a and 227b as in the aforementioned embodiments, or may correspond to those detected by the pressure detectors 227a, 227b, and 229 as in the aforementioned embodiments.

In a case where the pressure data storage 392 stores the history information in this way, when the difference between the newly detected pressure value and the previously detected pressure value is larger than a predetermined value (fourth threshold value), it may be determined that an abnormality has occurred in the substrate processing apparatus 10. For example, a value significantly larger than a difference between normally assumed pressure values may be set as the fourth threshold value.

That is, in these embodiments, when the difference between the newly obtained detection result by the pressure detector and the history information already stored in the pressure data storage 392 is larger than the predetermined value (fourth threshold value), it is determined that an abnormality has occurred and thus the controller 380 notifies warning information to notify an abnormality state or stops the operation of the substrate processing apparatus 10.

Thus, according to these embodiments, it is possible to suppress the processing of the substrate 200 in the abnormal state by notifying the warning information or stopping the operation of the apparatus, thereby maintaining high productivity.

### Other Embodiments

While the embodiments of the present disclosure haven been described above, the present disclosure is not limited to the aforementioned embodiments but may be variously modified without departing from the spirit of the present disclosure.

In each of the aforementioned embodiments, there have been described the methods in which films are formed by alternately supplying the precursor gas and the reaction gas. However, as long as a gas phase reaction amount of the precursor gas and the reaction gas or a generation amount of byproducts falls within an allowable range, the present disclosure may be applied to other methods. For example, the methods are those in which supply timings of the precursor gas and the reaction gas overlap.

Further, in each of the aforementioned embodiments, there have been described the film-forming process, but the present disclosure may be applied to other processes. For example, the other processes may include a diffusion process, an oxidation process, a nitriding process, an oxynitriding process, a reduction process, an oxidation-reduction process, an etching process, a heating process, and the like. For example, the present disclosure may also be applied to a process of plasma-oxidizing the surface of the substrate or the film formed on the substrate by using only the reaction gas or a plasma nitriding process. Further, the present disclosure may be applied to a plasma annealing process by using only the reaction gas.

Further, in each of the aforementioned embodiments, there have been described examples in which the silicon oxide film is formed by using the silicon-containing gas as the precursor gas and the oxygen-containing gas as the reaction gas, but the present disclosure may be applied to forming a film by using other gases. For example, the film may include an oxygen-containing film, a nitrogen-containing film, a carbon-containing film, a boron-containing film, a metal-containing film, a film containing a plurality of these elements, and the like. Furthermore, these films may include, for example, a SiN film, an AlO film, a ZrO film, a HfO film, a HfAlO film, a ZrAlO film, a SiC film, a SiCN film, a SiBN film, a TiN film, a TiC film, a TiAlC film, and the like. The same effects may be achieved by comparing gas characteristics (adsorbability, desorbability, vapor pressure or the like) of each of the precursor gas and reaction gas used to form these films and properly changing a supply position or an internal structure of the process chamber by comparison.

Further, in each of the aforementioned embodiments, there has been described the N₂ gas as the inert gas by way of example, but the present disclosure is not limited thereto as long as it does not react with the processing gas. For example, a rare gas such as a helium (He) gas, a neon (Ne) gas, and an argon (Ar) gas may be used as the inert gas.

Further, in each of the aforementioned embodiments, the expressions such as “equal (the same)” or “substantially equal (the same)” have been used for the pressure difference, but the present disclosure is not limited to a case where the respective pressure values are completely equal to each other. For example, substantially the same state such that a quality of substrate processing may be maintained may also be included.

According to the present disclosure in the embodiments of the present disclosure, it is possible to maintain high productivity when including a plurality of process chambers.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a plurality of process chambers in which substrates are processed;
a gas supplier configured to supply a gas to the process chambers;
a plurality of process chamber exhaust pipes respectively connected to the plurality of process chambers;
a common gas exhaust pipe disposed such that the respective process chamber exhaust pipes join together at downstream sides of the process chamber exhaust pipes;
at least one detector configured to detect states of pressures in the process chamber exhaust pipes; and
a plurality of inert gas supply pipes respectively connected to the process chamber exhaust pipes and configured to supply an inert gas into the process chamber exhaust pipes.

2. The substrate processing apparatus according to claim 1, wherein the at least one detector includes a plurality of detectors, and
wherein the detectors are installed at the process chamber exhaust pipes respectively.

3. The substrate processing apparatus according to claim 2, further comprising a regulator configured to control the supply of the inert gas from the inert gas supply pipes based on the states of pressures detected by the detectors.

4. The substrate processing apparatus according to claim 2, wherein the inert gas supply pipes are connected to the process chamber exhaust pipes at upstream sides of detection positions of the detectors.

5. The substrate processing apparatus according to claim 2, wherein a joining pipe pressure detector, which is a portion of the detectors, is installed at the common gas exhaust pipe.

6. The substrate processing apparatus according to claim 2, wherein the process chamber exhaust pipes each include a longitudinal pipe disposed along a longitudinal direction and a lateral pipe disposed along a lateral direction, and
wherein the inert gas supply pipes each are connected to the lateral pipe.

7. The substrate processing apparatus according to claim 2, wherein the supply of the inert gas from the inert gas supply pipes is performed such that a pressure difference among the pressures in the process chamber exhaust pipes detected by the detectors falls within a predetermined range.

8. The substrate processing apparatus according to claim 2, further comprising:
a pressure data storage configured to store a detection result of the detectors as history information; and
a controller configured to notify warning information when a difference between the detection result obtained by the detectors and the history information already stored in the pressure data storage is larger than a predetermined value.

9. The substrate processing apparatus according to claim 1, further comprising a regulator configured to control the supply of the inert gas from the inert gas supply pipes based on the states of the pressures detected by the at least one detector.

10. The substrate processing apparatus according to claim 9, wherein the inert gas supply pipes are connected to the process chamber exhaust pipes at upstream sides of detection positions of the at least one detector.

11. The substrate processing apparatus according to claim 9, wherein a joining pipe pressure detector, which is a portion of the at least one detector, is installed at the common gas exhaust pipe.

12. The substrate processing apparatus according to claim 9, wherein the process chamber exhaust pipes each include a longitudinal pipe disposed along a longitudinal direction and a lateral pipe disposed along a lateral direction, and
wherein the inert gas supply pipes each are connected to the lateral pipe.

13. The substrate processing apparatus according to claim 9, wherein the supply of the inert gas from the inert gas supply pipes is performed such that a pressure difference among the pressures in the process chamber exhaust pipes detected by the at least one detector falls within a predetermined range.

14. The substrate processing apparatus according to claim 9, further comprising:
a pressure data storage configured to store a detection result of the at least one detector as history information; and
a controller configured to notify warning information when a difference between the detection result obtained by the at least one detector and the history information already stored in the pressure data storage is larger than a predetermined value.

15. The substrate processing apparatus according to claim 1, wherein the inert gas supply pipes are connected to the process chamber exhaust pipes at upstream sides of detection positions of the at least one detector.

16. The substrate processing apparatus according to claim 1, wherein a joining pipe pressure detector, which is a portion of the at least one detector, is installed at the common gas exhaust pipe.

17. The substrate processing apparatus according to claim 1, wherein the process chamber exhaust pipes each include a longitudinal pipe disposed along a longitudinal direction and a lateral pipe disposed along a lateral direction, and
wherein the inert gas supply pipes each are connected to the lateral pipe.

18. The substrate processing apparatus according to claim 1, wherein the supply of the inert gas from the inert gas supply pipes is performed such that a pressure difference among the pressures in the process chamber exhaust pipes detected by the at least one detector falls within a predetermined range.

19. The substrate processing apparatus according to claim 1, further comprising:
a pressure data storage configured to store a detection result of the at least one detector as history information; and
a controller configured to notify warning information when a difference between the detection result obtained by the at least one detector and the history information already stored in the pressure data storage is larger than a predetermined value.
